(19) United States
(12) Patent Application Publication
(10) Pub. No.: US 2007/0010072 A1
(43) Pub. Date: Jan. 11, 2007

(54) Uniform batch film deposition process and films so produced

(75) Inventors: Robert Jeffrey Bailey, Santa Cruz, CA (US); Taiqing T. Qiu, Los Gatos, CA (US); Cole Porter, San Jose, CA (US); Olivier Laparra, San Jose, CA (US); Robert H. Chatham, Scotts Valley, CA (US); Martin Mogaard, Scotts Valley, CA (US); Helmuth Treichel, Milpitas, CA (US)

Correspondence Address: GIFFORD, KRASS, GROH, SPRINKLE & CITKOWSKI, P.C, PO BOX 7021, TROY, MI, 48007-7021, US

(73) Assignee: Aviza Technology, Inc., Scotts Valley, CA (US)

(21) Appl. No.: 11/482,887

(22) Filed: Jul. 7, 2006

Related U.S. Application Data
(60) Provisional application No. 60/697,784, filed on Jul. 9, 2005.

(51) Int. Cl. H01L 21/20

(52) U.S. Cl. 438/478

(57) ABSTRACT

A batch of wafer substrates is provided with each wafer substrate having a surface. Each surface is coated with a layer of material applied simultaneously to the surface of each of the batch of wafer substrates. The layer of material is applied to a thickness that varies less than four thickness percent across the surface and exclusive of an edge boundary and having a wafer-to-wafer thickness variation of less than three percent. The layer of material so applied is a silicon oxide, silicon nitride or silicon oxynitride with the layer of material being devoid of carbon and chlorine. Formation of silicon oxide or a silicon oxynitride requires the inclusion of a co-reactant. Silicon nitride is also formed with the inclusion of a nitrification co-reactant. A process for forming such a batch of wafer substrates involves feeding the precursor into a reactor containing a batch of wafer substrates and reacting the precursor at a wafer substrate temperature, total pressure, and precursor flow rate sufficient to create such a layer of material. The delivery of a precursor and co-reactant as needed through vertical tube injectors having multiple orifices with at least one orifice in registry with each of the batch of wafer substrates and exit slits within the reactor to create flow across the surface of each of the wafer substrates in the batch provides the within-wafer and wafer-to-wafer uniformity.

### RELATED APPLICATION

This application claims priority of U.S. Provisional Patent Application Ser. No. 60/697,784 filed Jul. 9, 2005, which is incorporated herein by reference.

### FIELD OF THE INVENTION

The present invention relates generally to depositing a layer of silicon-nitrogen, silicon-oxygen, or silicon-nitrogen-oxygen material simultaneously on a plurality of substrates and in particular to the use of a silylamine precursor in combination with a across-flow liner to achieve a degree of within-wafer and wafer-to-wafer uniformity while improving impurity profiles to form silicon-oxygen, silicon-nitrogen, or silicon-nitrogen-oxygen materials.

### BACKGROUND OF THE INVENTION

Thermal processing apparatuses are commonly used in the manufacture of integrated circuits (ICs) or semiconductor devices from semiconductor substrates or wafers. Thermal processing of semiconductor wafers include, for example, heat treating, annealing, diffusion or driving of dopant material, deposition or growth of layers of material, and etching or removal of material from the substrate. These processes often call for the wafer to be heated to a temperature as high as 1300° C. and as low as 300° C. before and during the process, and that one or more fluids, such as a process gas or reactant, be delivered to the wafer. Moreover, these processes typically require that the wafer be maintained at a uniform temperature throughout the process, despite variations in the temperature of the process gas or the rate at which it is introduced into the process chamber.

Silicon nitride, silicon dioxide, and silicon oxynitride are dielectric materials widely used in the manufacture of semiconductor devices. These films are typically deposited from silicon sources such as silane (SiH₄), disilane (Si₂H₆), dichlorosilane (DCS) (SiCl₂H₂), organosilanes and others with various reactant sources such as ammonia (NH₃), oxygen (O₂), ozone (O₃), nitrous oxide (N₂O), nitrogen dioxide (NO₂), nitric oxide (NO), and others depending on the desired material composition. Additionally, ozone (O₃) has been investigated as a potential species for the direct formation of SiO₂ when reacted with exposed Si surfaces. The temperatures of these processes are typically greater than 600° C. The high speed requirements of advanced semiconductor devices dictate that the overall thermal budget of the device manufacture be lowered. This is driving the need to reduce the processing temperature of dielectric layers to below 550° C. and preferably below 500° C. The most desired deposition temperature would be 400° C. or lower. Several new silicon precursors have been developed to address the need for lower temperature dielectric deposition.

In addition to high deposition temperatures associated with conventional batch process chemical vapor deposition, there is a growing appreciation that contaminants associated with these processes limit the effectiveness of the deposited materials to perform as intended barrier or insulative layers. By way of example, the use of a chlorinated silane precursor or co-reactant leads to chlorine incorporation into a deposited layer to the detriment of the material performance. In the case of silicon nitride deposition, reaction of a chlorinated silane with ammonia yields ammonium chloride that clogs reactor exhaust ports and also condenses on deposited layers thereby forcing the wafer substrate to remain at elevated temperatures subsequent to deposition so as to increase the thermal budget, reduce throughput, and invariably still incorporate a diffusible chlorine contaminant.

Efforts to address the process and performance limitations associated with chlorinated deposition precursors have led to the usage of various organosilanes. Unfortunately, these precursors have met with limited acceptance owing to coking during material deposition. The inclusion of carbon within a deposited material as a result of incomplete pyrolysis not only diminishes the electrically insulative properties of the resulting material but also creates a concern about diffusion of carbon that can poison device semiconductor elements.

These problems associated with chlorine and carbon inclusion have led to the exploration of various silylamines. As silylamines contain a silicon-nitrogen bond, these precursors have garnered attention as typically having lower deposition temperatures and have better contaminant inclusion profiles than analogous chlorosilanes and organosilanes. In the case of the unsubstituted silylamines, neither carbon nor chlorine is present and the resulting deposited layer of material is free of carbon and chlorine contaminants. Silylamines tend to incorporate hydrogen as an impurity that migrates readily and diminishes material performance. While deposition of silicon nitride and silicon oxynitride from silylamines such as trisilylamine has been reported, little attention has been paid to hydrogen content of the resulting films or batch deposition of such materials. US 2005/0100670 A1 is representative of these efforts.

A conventional batch thermal processing apparatus typically includes a process chamber positioned in or surrounded by a furnace. Substrates to be thermally processed are sealed in the process chamber and heated to a desired temperature at which the deposition reaction is performed. For many processes, such as Chemical Vapor Deposition (CVD), the sealed process chamber is first evacuated to a desired process pressure, and once the process chamber has reached the desired temperature, reactive or process gases are introduced to form or deposit reactant species on the substrates. Various forms of CVD can be performed including low pressure (LPCVD), plasma enhanced (PECVD), and thermal CVD to name but a few with the choice of technique specifics involving a balancing of factors inclusive of thermal budget, desired film uniformity and porosity, and contaminant limits. To date, efforts to achieve satisfactory batch material layer deposition with satisfactory within-wafer (WIW) and wafer-to-wafer (WTW) uniformity have met with limited success.

Thermal oxidation produces high quality silicon dioxide films, which are important for electrical isolation of active regions of electronic devices. Typically, thermal oxidation is carried out using O₂ (dry oxidation) or steam (wet oxidation) at temperatures ranging from 750° C. to 1150° C. at atmospheric pressure or slightly below atmospheric pressure.

Thermal oxidation, however, has several limitations. The rate of thermal oxidation depends strongly on the crystal orientation of silicon surfaces. Due to the high packing density of (111) surfaces, oxidation on the (111) surfaces is significantly higher than that on (100) surfaces. Shallow trench isolation (STI) for logic applications and trench isolation for DRAM applications involve (100), (110) and (111) silicon surfaces in the trench. It has been very difficult to produce a uniform oxide liner on trench surfaces with rounded and stress-released trench corners, which in turn causes leakage in logic devices and reduction of data retention time in DRAM devices. Additionally, the rate of thermal oxidation is sensitive to the nature and amount of implanted dopants and also differs between single-crystal and polycrystalline silicon surfaces, so as to hamper further scaling of flash memory devices. To improve thermal oxidation uniformity requires oxidation at low pressures of about 5 torr, thereby limiting throughput.

Thus, there exists a need for a process able to yield a wafer substrate batch having a layer of silicon nitride, silicon oxide, or silicon oxynitride thereon with WIW and WTW uniformity at moderate temperature and tolerable contaminant profiles.

### SUMMARY OF THE INVENTION

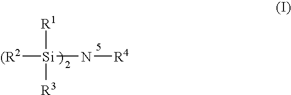

A batch of wafer substrates is provided with each wafer substrate having a surface. Each surface is coated with a layer of material applied simultaneously to the surface of each of the batch of wafer substrates. The layer of material is applied to a thickness that varies less than four thickness percent across the surface and exclusive of an edge boundary and having a wafer-to-wafer thickness variation of less than three percent. The layer of material so applied is a silicon oxide, silicon nitride or silicon oxynitride with the layer of material being devoid of carbon and chlorine. The material deposition occurs ideally below 600° C. A silicon nitride layer of material is formed from a precursor having the Formula I or II alone or in combination with a coreactant: 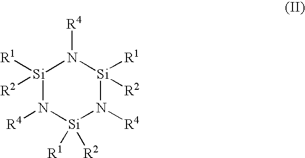
where R¹, R² and R³ are each independently hydrogen or C₁₋₈ alkyl, R¹ is SiH₃ when R₂ and R₃ are both hydrogen, and R⁴ is hydrogen, C₁₋₈ alkyl, or Si bonded to R¹, R² and R³. Formation of silicon oxide or a silicon oxynitride requires the inclusion of a co-reactant. Silicon nitride is also formed with the inclusion of a nitrification co-reactant.

A process for forming such a batch of wafer substrates involves feeding the precursor into a reactor containing a batch of wafer substrates and reacting the precursor at a wafer substrate temperature, total pressure, and precursor flow rate sufficient to create such a layer of material. The delivery of a precursor and co-reactant as needed, through vertical tube injectors having multiple orifices with at least one orifice in registry with each of the batch of wafer substrates and exit slits within the reactor creates flow across the surface of each of the wafer substrates in the batch to yield the aforementioned within-wafer and wafer-to-wafer uniformity.

### BRIEF DESCRIPTION OF THE DRAWING

FIG. 1 is a cross-sectional view of a thermal processing apparatus having an across-flow injector system according to an embodiment of the present invention;

FIG. 2 is a cross-sectional side view of a portion of the thermal processing apparatus of FIG. 1 showing positions of injector orifices in relation to the liner and of exhaust slots in relation to the wafers according to an embodiment of the present invention;

FIG. 3 is a plan view of a portion of the thermal processing apparatus of FIG. 1 taken along the line A-A of FIG. 1 inclusive of a stepped liner accommodating tube injectors and showing gas flow from injector orifices across a wafer and to an exhaust port;

FIG. 4 is a perspective downward view of an across-flow stepped liner showing a longitudinal bulging section according to one embodiment of the present invention;

FIG. 5 is a perspective downward view of an across-flow stepped liner showing a plurality of exhaust slots in the liner according to one embodiment of the present invention;

FIG. 6 is a side view of an across-flow liner of FIGS. 4 and 5;

FIG. 7 is a top plan view of an across-flow liner depicted in FIGS. 4-6;

FIG. 8 is a magnified top plan view of the bulging portion of across-flow liner depicted in FIG. 7;

FIG. 9 is a perspective view of an across-flow injection system;

FIG. 10 is a perspective view of another embodiment of an across-flow injection system;

FIG. 11 is a plan view of an across-flow liner with a bulging section showing gas flow from orifices directing to the center of a wafer and exiting an exhaust slot according to one embodiment of the present invention;

FIG. 12 is a plan view of an across-flow liner with a bulging section showing gas flow from orifices that impinges the liner inner wall prior to flowing across a wafer and exiting an exhaust slot according to one embodiment of the present invention;

FIG. 13 is a plan view of an across-flow liner with a bulging section showing gas flow from orifices that impinges on each other and the liner inner wall prior to flowing across a wafer and exiting an exhaust slot according to one embodiment of the present invention;

FIG. 14 is a graphical representation showing gas flow lines across the surface of a wafer inside a chamber including an across-flow liner and two injection tubes having injection orifices facing the liner inner wall according to one embodiment of the present invention;

FIG. 15 is a graphical representation showing gas flow lines across the surface of a wafer inside a chamber including a prior art liner and two injection tubes having injection orifices facing the liner inner wall;

FIG. 16 is a graphical representation showing gas flow lines across the surface of a wafer inside a chamber including an across-flow liner and two injection tubes having injection orifices facing each other according to one embodiment of the present invention;

FIG. 17 is a graphical representation showing gas flow lines across the surface of a wafer inside a chamber including a prior art liner and two injection tubes having injection orifices facing each other;

FIG. 18 is a graphical representation showing gas flow lines across the surface of a wafer inside a chamber including an across-flow liner and two injection tubes having injection orifices facing the center of a wafer according to one embodiment of the present invention;

FIG. 19 is a graphical representation showing gas flow lines across the surface of a wafer inside a chamber including a prior art liner and two injection tubes having injection orifices facing to the center of a wafer;

FIG. 20 is computational flow dynamics (CFD) demonstration for a thermal processing apparatus including an across-flow liner and an injection system having injection ports facing the liner inner wall in accordance with one embodiment of the present invention;

FIG. 21 is CFD demonstration for a thermal processing apparatus including an across-flow liner and an injection system having injection ports facing each other in accordance with one embodiment of the present invention;

FIG. 22 is CFD demonstration for a thermal processing apparatus including an across-flow liner and an injection system having injection ports facing the center of a substrate in accordance with one embodiment of the present invention;

FIG. 23 is a CFD demonstration of the atomic oxygen concentration across the load for a conventional “up-flow” configuration reactor lacking a liner of FIGS. 11-13;

FIG. 24 is a CFD demonstration of the atomic oxygen concentration across the load for a across-flow configuration;

FIG. 25 is an exemplary gas flow schematic for a two injector reactor of FIG. 1.

FIG. 26 is a graph depicting low-T oxide material layer deposition and within-wafer (WIW) to one sigma as a function of deposition temperature.

### DETAILED DESCRIPTION OF THE PREFERRED EMBODIMENTS

The present invention has utility as a batch of semiconductor wafer substrates having deposited thereon a layer of a silicon nitride material, silicon oxide material, or silicon oxynitride material, the material layer exhibiting within-wafer uniformity of less than four thickness percent three sigma and a wafer-to-wafer uniformity of less than three thickness percent that are simultaneously produced absent carbon and chloride contamination. A process to achieve such a batch of wafer substrates is provided utilizing across-flow dispersion of reactants relative to a wafer substrate surface.

As used herein within-wafer (WIW) variation is defined as the topological thickness variation across a 300 mm planar wafer substrate between the thinnest and thickest material layer deposited exclusive of an edge zone of 3 mm edge exclusion and shadow regions associated with a wafer carrier boat rail.

As used herein, wafer-to-wafer (WTW) variation is defined as the maximal difference in average thickness in a material layer between a batch of multiple wafers simultaneously processed for layer deposition.

A silicon-nitrogen-silicon (Si—N—Si) structure containing precursor is used to produce an inventive layer of a material simultaneously to a batch of wafer substrates. Preferably, the precursor is stable under an inert atmosphere at 20° C. An inventive precursor in acyclic form has the general formula: 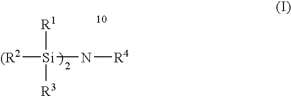
Preferably, when the precursor has the structure according to Formula I, R¹, R² and R³ in every occurrence are identical. More preferably, R¹, R² and R³ are all hydrogen. Most preferably, R⁴ is the silicon bonded to R¹, R² and R³ where R¹, R² and R³ are all hydrogen and Formula (I) corresponds to trisilylamine (TSA).

A silicon-nitrogen-silicon structure containing cyclic precursor has the structure:

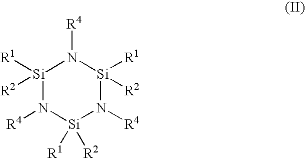

where R¹, R² and R⁴ have the identities as detailed above with respect to the acyclic precursor of Formula I. Preferably, R¹ and R² in every occurrence are identical and R⁴ in every occurrence is identical. More preferably, R¹ in every occurrence is hydrogen, R² in every occurrence is hydrogen, and R⁴ is hydrogen or SiH₃. It is noted that the inventive precursors of Formulas (I) and (II) are devoid of halogen moieties specifically exclusive of chlorine, and as a result the resulting layer of material deposited is independent of chlorine contaminants and chlorine/chloride containing volatile byproducts. A layer of material is deposited according to the present invention that is substantially devoid of carbon inclusion even though the precursor of Formula I or II includes alkyl moieties. However, the avoidance of carbon infiltrates into a deposited inventive layer of material typically requires that deposition rates be adjusted to under 10 Angstroms per minute. The deposition of inventive material layers devoid of carbon was readily accomplished through the selection of a precursor containing only silicon, nitrogen and hydrogen atoms.

Mixtures of multiple precursors as detailed above are appreciated to be operative herein as well as the use of an inventive precursor with traditional silicon containing precursor compounds. Additionally, it is recognized that inventive precursor compounds may contain minor amounts of impurities that may be incorporated into an inventive material layer. Such impurity incorporation is diminished to acceptable levels through additional precursor purification prior to usage and storage under nonreactive conditions. Additionally, it is appreciated that an inventive precursor is stored with an inert diluent or metered through a reaction chamber with such a diluent with conventional techniques such as the employ of a mass flow controller (MFC).

Formation of a layer Si_{y}N where y is between 0.75 and 1 is noted to readily occur upon injecting a precursor into a reaction chamber with the wafer batch typically held at a temperature range of between 450° C. and 800° C. In instances where y is less than 1 and the precursor of Formula I or II is devoid of alkyl moieties, y-1 corresponds to the amount of hydrogen intercalation into the resultant silicon nitride material layer.

It is appreciated that annealing a hydrogen containing silicon nitride material layer in the presence of a nitrogen source such as ammonia subsequent to deposition removes hydrogen from the layer and increases the nitrogen content of the resulting layer to the point where nitrogen-rich silicon nitride (Si₃N₄) is achieved. While the hydrogen depleting annealing can occur at temperatures above 400° C., the kinetics of such anneal increase with temperature. In instarices where thermal budget of a wafer substrate is an issue, rapid thermal processing and other flash annealing techniques are appreciated to be operative.

In addition to pyrolysis of a precursor of Formula I or II, the deposition mechanism and/or film composition is altered by reacting a precursor of Formulas (I) and (II) with a nitrifying or oxidizing co-reactant. Such co-reactants illustratively include NH₃, HN₃, H₂N₂, secondary amines, tertiary amines, NH* radicals, NH₂*radicals, O₂, O₃, O* radicals, OH* radicals, H₂O, H₂O₂, NO, N₂O, and NO₂. Preferably, the co-reactant is devoid of carbon atoms and chlorine atoms. The co-reactant, if present, is injected into a reaction chamber either in concert with the precursor of Formula I or II, in an alternating pulsatile flow relative to the precursor, or after deposition of a material layer from the precursor has occurred. Post deposition introduction of the coreactant results in a post-processing modification. In instances where one desires to deposit a layer of silicon dioxide, preferably an oxygen containing co-reactant such as oxygen, ozone, water or a combination thereof is injected into the reactor volume in concert with the precursor of Formula I or II. Likewise, a layer of a material having a stoichiometry with little variation through the thickness of the layer is produced by injecting nitrogen and oxygen containing co-reactants into the reactor with the precursor of Formula I or II. Silicon oxynitride precursors include NOx molecules; a combination of an oxidizing precursor and a nitrifying precursor, such as ammonia; or combinations thereof. Production of a batch of wafer substrates containing a layer of material applied simultaneously thereto according to the present invention typically occurs at a pressure of less than 50 Torr and preferably less than 10 Torr. More preferably, the reactor pressure is maintained between 100 millitorr and 7 Torr total pressure through resort to an inert diluent gas to deposit a material layer. Inert diluent gases illustratively include the noble gases, dinitrogen or combinations thereof. It is appreciated that deposition rates of a layer of material vary considerably based not only on the material being deposited but also on flow rates, total reaction pressure, and temperature. One of skill in the art will appreciate that deposition rates of the deposition of all the inventive materials tend to increase with increases in temperature, precursor flow rate, and total pressure. The nature of such parameters will be further detailed with respect to the following examples.

The deposition of various material layers according to the present invention and the conditions under which such deposition occurs where the precursor of Formula I or II is supplied at a flow rate of between 1 and 50 sccm is detailed in Table 1 where the units for the coreactant flow rate and inert diluent flow rate are in multiples of precursor flow rate.

TABLE 1
Typical Layer Deposition Conditions

| | Coreactant Flow Rate | Optional Inert Diluent | |
|---|---|---|---|
| | (multiple of | (multiple of | Deposition |
| Material | precursor flow rate) | precursor flow rate) | Temp. (° C.) |
| Si_{y}N | e.g. NH₃ 0-80x | 10-200x | 480-600 |
| SiOₓ | e.g. O₂ 5-100x | 10-200x | 200-600 |
| SiOₘNₙ | e.g. N₂O 3-100x | 10-200x | 480-600 |

It is appreciated that a number of co-reactants detailed herein are in equilibrium with radical species. Without intending to be bound to a particular mechanistic theory, such radical species are believed to be involved in material layer deposition at the comparatively low temperatures of the present invention as compared to the prior art. The singlet oxygen (O*) formation from ozone and NO* formation from N₂O are exemplary of known radical species formed under the temperature and pressure conditions detailed in Table 1. Optionally, radical species concentration generation is enhanced through the inclusion of the radical generator with which a precursor of Formula I or II, a co-reactant, or a combination thereof is exposed in the course of the material layer deposition process. Conventional radical generating sources operable within the context of the present invention include plasma discharge electrodes, photolysis sources, and rapid thermal in-situ steam generation (ISSG) processing. One of ordinary skill in the art will appreciate that while radical species concentration increase associated with the addition of a free radical generator tends to decrease the required deposition temperature, care is required to maintain reaction condition uniformity across a wafer surface and throughout a wafer batch reactor volume.

A reactor well suited to yield material layer deposition in a batch process such that a batch of wafer substrates each receive a layer of material on a deposition surface simultaneously to a thickness of greater than 15 Angstroms such that the thickness of the material layer applied to each wafer surface varies less than four percent three sigma WIW and less than three percent in layer thickness WTW. Such a reactor overcomes problems associated with uniform precursor distribution within a batch chamber and utilizes elongated injector tubes rotatable about a tube axis with the injector tubes including orifices in registry with wafer carrier positions and a series of exit slits so as to create a flow across the multiple wafer surfaces of a batch in a laminar across flow pattern. Such a reactor is disclosed in WO 2005/031233 filed Sep. 22, 2004. Such a reactor is currently commercially available from Aviza Technology (Scotts Valley, Calif.).

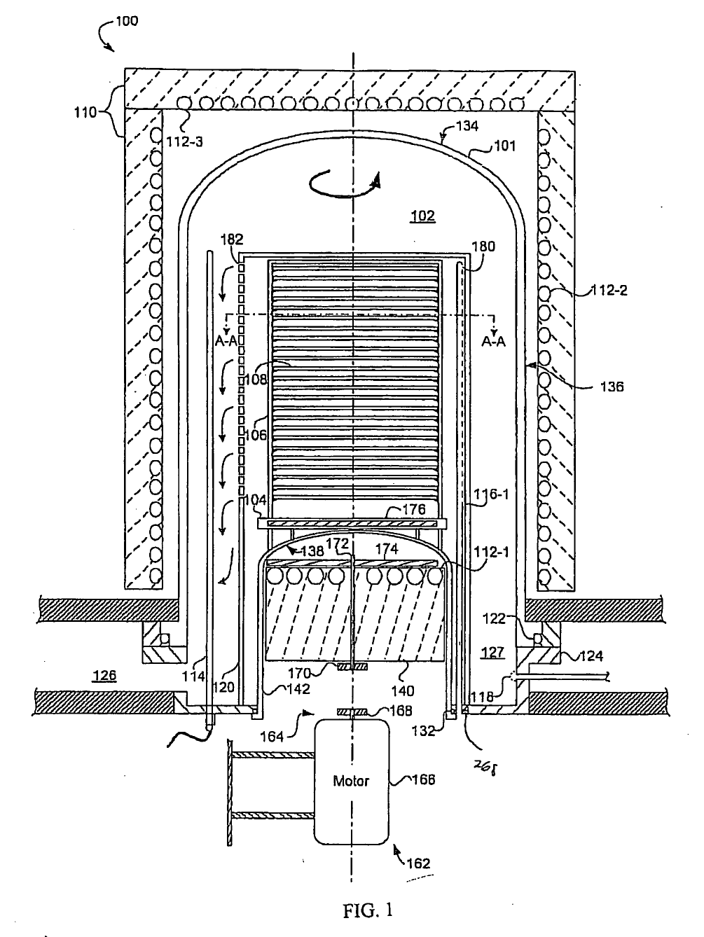

As shown in FIG. 1, improved injectors 116 are used in the thermal processing apparatus 100. The injectors 116 are distributive or across-flow injectors 116-1 in which process gas or vapor is introduced through injector openings or orifices 180 on one side of the wafers 108 held in boat 106 and caused to flow across the surfaces of the wafers 108 in a laminar flow to exhaust ports or slots 182. The exhaust slots 182 are aligned 180 degrees from the injector system 116. In the alternative, the exhaust slots 182 are aligned at some other angle from the injectors 116. The across-flow injector system 116 improves wafer uniformity within a batch of wafers 108 by providing an improved distribution of process gas or vapor over earlier gas flow configurations.

Additionally, across-flow injectors 116 can serve other purposes, including the injection of diluent gases between the wafers 108. Use of across-flow injectors 116 results in a more uniform cooling between wafers 108 whether a wafer substrate is disposed at the bottom, top or middle of the stack of wafers, as compared with earlier gas flow configurations. Preferably, the injector 116 orifices 180 are sized, shaped and positioned to provide a spray pattern that promotes forced convective cooling between the wafers 108 in a manner that does not create a large temperature gradient across the wafer.

FIG. 1 is a cross-sectional view of an embodiment of a thermal processing apparatus for thermally processing a batch of semiconductor wafers. As shown, the thermal processing apparatus 100 generally includes a vessel 101 that encloses a volume to form a process chamber 102 having a support 104 adapted for receiving a carrier or boat 106 with a batch of wafers 108 held therein, and heat source or furnace 110 having a number of heating elements 112-1, 112-2 and 112-3 (referred to collectively hereinafter as heating elements 112) for raising a temperature of the wafers to the desired temperature for thermal processing. The thermal processing apparatus 100 further includes one or more optical or electrical temperature sensing elements, such as a resistance temperature device (RTD) or thermocouple (T/C), for monitoring the temperature within the process chamber 102 and controlling operation of the heating elements 112. In the embodiment shown in FIG. 1, the temperature sensing element is a profile T/C 114 that has multiple independent temperature sensing nodes or points (not shown) for detecting the temperature at multiple locations within the process chamber 102. The thermal processing apparatus 100 can also include one or more injectors 116, one of which 116-1 for introducing a fluid, such as a gas or vapor, into the process chamber 102 for processing or cooling the wafers 108, and one or more purge ports or vents 118 (only one of which is shown) for introducing a gas to purge the process chamber and cool the wafers. A liner 120 increases the concentration of processing gas or vapor near the wafers 108 in a process zone 128 in which the wafers are processed, and reduces contamination of the wafers from flaking or peeling of deposits that can form on interior surfaces of the process chamber 102. Processing gas or vapor exits the process zone through exhaust ports or slots 121 in the chamber liner 120.

Generally, the vessel 101 is sealed by a seal, such as an O-ring 122, to a platform or base plate 124 to form the process chamber 102, which completely encloses the wafers 108 during thermal processing. The dimensions of the process chamber 102 and the base plate 124 are selected to provide a rapid evacuation, rapid heating and a rapid backfilling of the process chamber. Advantageously, the vessel 101 and the base plate 124 are sized to provide a process chamber 102 having dimensions selected to enclose a volume substantially no larger than necessary to accommodate the liner 120 with the carrier 106 and wafers 108 held therein. Preferably, the vessel 101 and the base plate 124 are sized to provide a process chamber 102 having dimensions of from about 125% to about 150% of that necessary to accommodate the liner 120 with the carrier 106 and wafers 108 held therein, and more preferably, the process chamber has dimensions no larger than about 125% of that necessary to accommodate the liner 120 and the carrier 106 and wafers 108 in order to minimize the chamber volume and thereby reduce pump down and backfill time required.

Openings for the injectors 116, T/Cs 114 and vents 118 are sealed using seals such as o-rings, VCR®, or CF® fittings. Gases or vapor released or introduced during processing are evacuated through a foreline or exhaust port 126 formed in a wall of the process chamber 102 (not shown) or in a plenum 127 of the base plate 124, as shown in FIG. 1. The process chamber 102 can be maintained at atmospheric pressure during thermal processing or evacuated to a vacuum as low as 5 milliTorr through a pumping system (not shown) including one or more roughing pumps, blowers, hi-vacuum pumps, and roughing, throttle and foreline valves. In the alternative, the process chamber can be evacuated to a vacuum lower than 5 milliTorr.

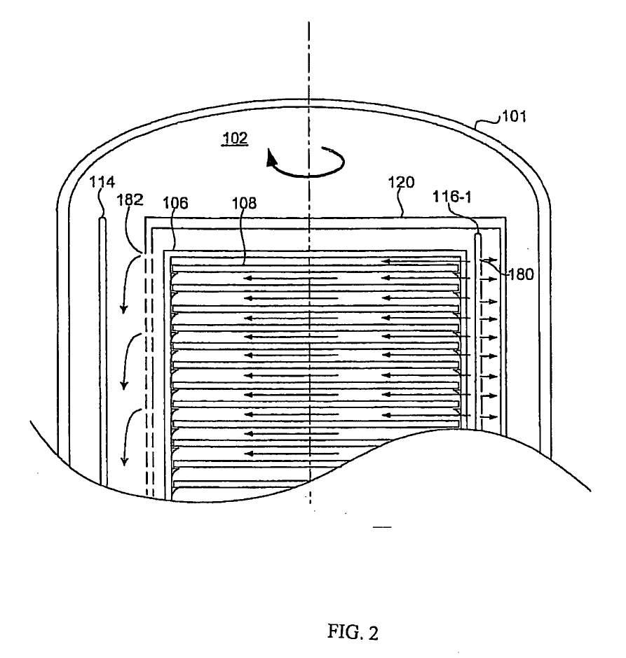

In another embodiment, shown in FIG. 2, the base plate 124 further includes a substantially annular flow channel 129 adapted to receive and support an injector 116 including a ring 131 from which depend a number of vertical injector tube or injectors 116-1. The injectors 116-1 can be sized and shaped to provide an up-flow, down-flow or across-flow flow pattern, as described below. The ring 131 and injectors 116-1 are located so as to inject the gas into the process chamber 102 between the boat 106 and the vessel 101.

The vessel 101 and liner 254 can be made of any metal, ceramic, crystalline or glass material that is capable of withstanding the thermal and mechanical stresses of high temperature and high vacuum operation, and which is resistant to erosion from gases and vapors used or released during processing. Preferably, the vessel 101 and liner 120 are made from an opaque, translucent or transparent quartz glass having a sufficient thickness to withstand the mechanical stresses of the thermal processing operation and resist deposition of process byproducts. By resisting deposition of process byproducts, the vessel 101 and liner 254 reduce the potential for contamination of the processing environment. More preferably, the vessel 101 and liner 254 are made from quartz that reduces or eliminates the conduction of heat away from the process zone in which the wafers 108 are processed.

The thermal processing apparatus 100 further includes a magnetically coupled wafer rotation system 162 that rotates the support 104 and the boat 106 along with the wafers 108 supported thereon during processing. In the alternative, the thermal apparatus 100 uses a rotational ferrofluidics seal (not shown) to rotate the support 104 and the boat 106 along with the wafers 108 supported thereon during processing. Rotating the wafers 108 during processing improves within-wafer (WIW) uniformity by averaging out any nonuniformities in temperature and process gas flow to create a uniform wafer temperature and species reaction profile. Generally, the wafer rotation system 162 is capable of rotating the wafers 108 at a speed of from about 0.1 to about 10 revolutions per minute (RPM).

The wafer rotation system 162 includes a drive assembly or rotating mechanism 164 having a rotating motor 166, such as an electric or pneumatic motor, and a magnet 168 encased in a chemically resistive container, such as annealed polytetrafluoroethylene or stainless steel. A steel ring 170 located just below the insulating block 140 of the pedestal 130, and a drive shaft 172 with the insulating block transfer the rotational energy to another magnet 174 located above the insulating block in a top portion of the pedestal. The steel ring 170, drive shaft 172 and second magnet 174 are also encased in a chemically resistive container compound. The magnet 174 located inside of the pedestal 130 magnetically couples through the crucible 142 with a steel ring or magnet 176 embedded in or affixed to the support 104 in the process chamber 102.

Magnetically coupling the rotating mechanism 164 through the pedestal 130 eliminates the need for locating the rotating mechanism 164 within the processing environment or for having a mechanical feedthrough, thereby eliminating a potential source of leaks and contamination. Furthermore, locating rotating mechanism 164 outside and at some distance from the process chamber 102 minimizes the maximum temperature to which it is exposed, thereby increasing the reliability and operating life of the wafer rotation system 162.

In addition to the above, the wafer rotation system 162 can further include one or more sensors (not shown) to ensure proper boat 106 position and proper magnetic coupling between the steel ring or magnet 176 in the process chamber 102 and the magnet 174 in the pedestal 130. A boat position verification sensor which determines the relative position of the boat 106 is particularly useful. In one embodiment, the boat position verification sensor includes a sensor protrusion (not shown) on the boat 106 and an optical or laser sensor located below the base plate 124. In operation, after the wafers 108 have been processed the pedestal 130 is lowered about 3 inches below the base plate 124. There, the wafer rotation system 162 is commanded to turn the boat 106 until the boat sensor protrusion can be seen. Then, the wafer rotation system 162 is operated to align the boat so that the wafers 108 can be unloaded. After this is done, the boat is lowered to the load/unload height.

FIG. 2 is a cross-sectional side view of a portion of the thermal processing apparatus 100 of FIG. 1 showing illustrative portions of the injector orifices 180 in relation to the liner 120 and the exhaust slots 182 in relation to the wafers 108, where like numerals correspond to those detailed with respect to FIG. 1.

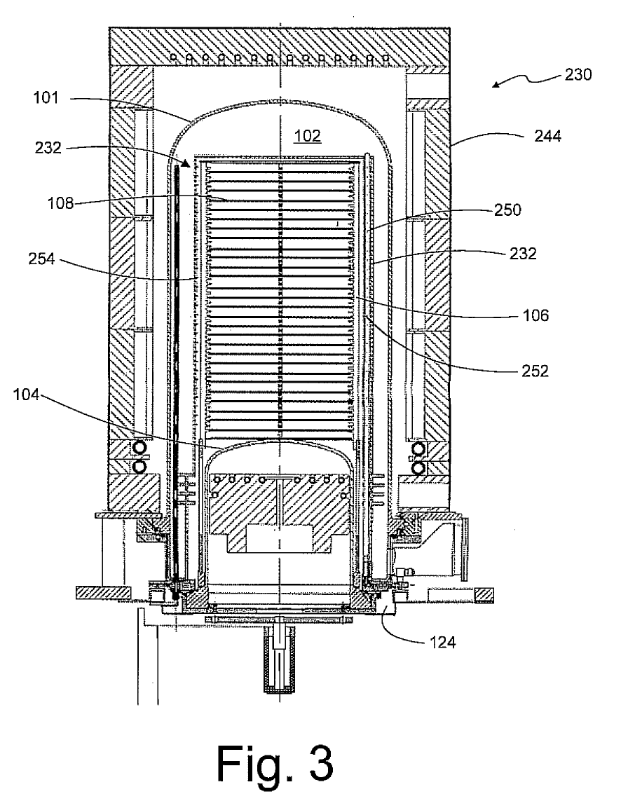

FIG. 3 shows a thermal processing apparatus 230 including an across-flow liner 232 operative with the present invention. To simplify description of the invention, elements not closely relevant to the invention are not indicated in the drawing or described. In general, the apparatus 230 includes a vessel 101 that forms a process chamber 102 having a support 104 adapted for receiving a carrier 106 with a batch of wafers 108 held therein. The apparatus 230 includes a heat source or furnace 112-2 that heats the wafers 108 to the desired temperature for thermal processing. An across-flow liner 232 is provided to increase the concentration of processing gas or vapor near wafers 108 and reduce contamination of wafers 108 from flaking or peeling of deposits that can form on interior surfaces of the vessel 101. The liner 232 is patterned to conform to the contour of the wafer carrier 106 and sized to reduce the gap between the wafer carrier 106 and the liner 232. The liner 232 is mounted to the base plate 124 and sealed.

Stepped liners are typically used in traditional up-flow vertical furnaces to increase process gas velocities and diffusion control. They are also used as an aid to improve within-wafer uniformity. Unfortunately, stepped liners do not correct down-the-stack-depletion problems, which occur due to single injection point of reactant gases forcing all injected gases to flow past all surfaces down the stack. In prior art vertical across-flow furnaces, the down-the-stack-depletion problem is solved. However, a flow path of least resistance may be created in the gap region between the wafer carrier and the liner inner wall instead of between the wafers. This least resistance path may cause vortices or stagnation which are detrimental to manufacturing processes. Vortices and stagnation in a furnace may create across-wafer nonuniformity problems for some process chemistries.

The present invention provides an across-flow liner that significantly improves the within-wafer uniformity by providing uniform gas flow across the surface of each substrate supported in a carrier. In general, the across-flow liner of the present invention includes a longitudinal bulging section to accommodate an across-flow injection system so that the liner can be patterned and sized to conform to the wafer carrier. The gap between the liner and the wafer carrier is significantly reduced, and as a result, vortices and stagnation as occurred in prior art furnaces can be reduced or avoided.

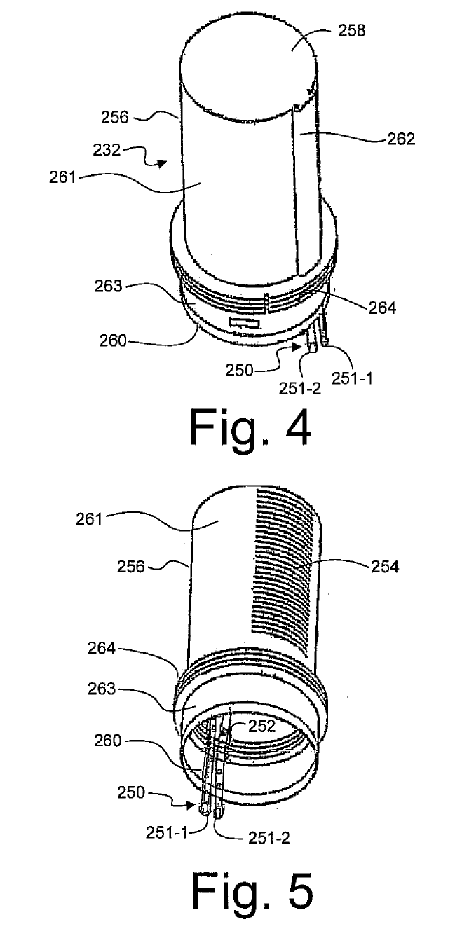

Referring to FIGS. 4-8, an across-flow injection system 116 is disposed within a long-bulging section 262 of the liner 232. Gases are introduced through a plurality of injection port orifices 252 from one side of the wafers 108 and carrier 106 and flow across the surface of the wafers in a laminar flow as described below. A plurality of slots 254 are formed in the liner 232 in a location approximately 180 degrees from the long-bulging section 262. The size and pattern of the slots 254 are predetermined and preferably cooperate with the spacing between and number of the injection orifices 180 or 252.

The across-flow liner can be made of any metal, ceramic, crystalline or glass material that is capable of withstanding the thermal and mechanical stresses of high temperature and high vacuum operation, and which is resistant to erosion from gases and vapors used or released during processing. Preferably, the across-flow liner 232 is made from an opaque, translucent or transparent quartz glass. In one embodiment, the liner is made from quartz that reduces or eliminates the conduction of heat away from the region or process zone in which the wafers are processed.

In general, the across-flow liner 232 includes a cylinder 256 having a closed end 258 and an open end 260. The cylinder 256 is provided with the longitudinal bulging section 262 having an inner wall 270 to accommodate an across-flow injection system (not shown). Preferably the bulging section 262 extends the substantial length of the cylinder 256. The plurality of latitudinal slots 254 are radial in their length and longitudinally located along the cylinder 256.

The across-flow liner 232 is sized and patterned to conform to the contour of the wafer carrier 106 and the carrier support 104. In one embodiment, the liner 232 comprises a first section 261 sized to conform to the wafer carrier 100 and a second section 263 sized to conform to the carrier support 104. The diameter of the first section 261 may differ from the diameter of the second section 263, i.e., the liner 232 may be “stepped” to conform to the wafer carrier 106 and carrier support 104 respectively. In one embodiment, the first section 261 of the liner 232 has an inner diameter that constitutes about 104% to 110% of the wafer carrier 106 outer diameter. In another embodiment, the second section 263 of the liner 232 has an inner diameter that constitutes about 115% to 120% of the outer diameter of the carrier support 104. The second section 263 may be provided with one or more heat shields 264 to protect seals such as O-rings from being overheated by heating elements.

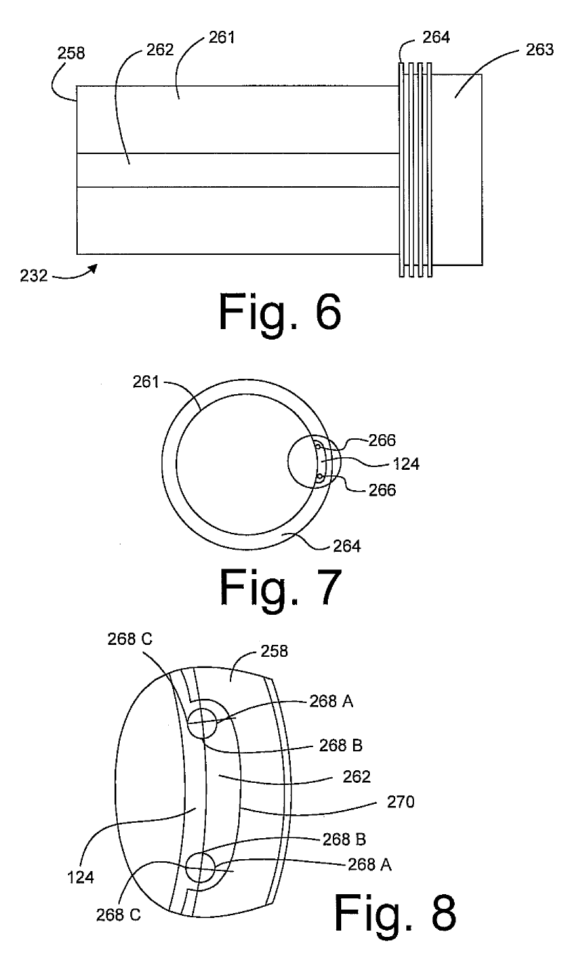

FIG. 6 is a side view of the across-flow liner 232. The longitudinal bulging section 262 extends the length of the first section 261. The injection system 250 (not shown) is accommodated in the bulging section 262 and introduces one or more gases into the across-flow liner 232 between the wafers 242. One or more heat shields 264 can be provided in the second section 263.

FIG. 7 is a top plan view of the across-flow liner 232 showing the closed end 258 of the cylinder 256 having openings 266 for receiving the across-flow injection system 250. The injection system 250 has at least one injection tube 251 (described in detail below) to fit within the openings 266. As shown in detail in FIG. 8, the openings 266 in the closed end 258 have notches 268 for orienting and stabilizing an across-flow injection system. Although three notches (268A, 268B, 268C) are shown in the openings 266 for illustrative purpose, it should be noted that any number of notches can be formed so that the injection tube can be oriented to any direction relative to the across-flow liner 232 and to each other.

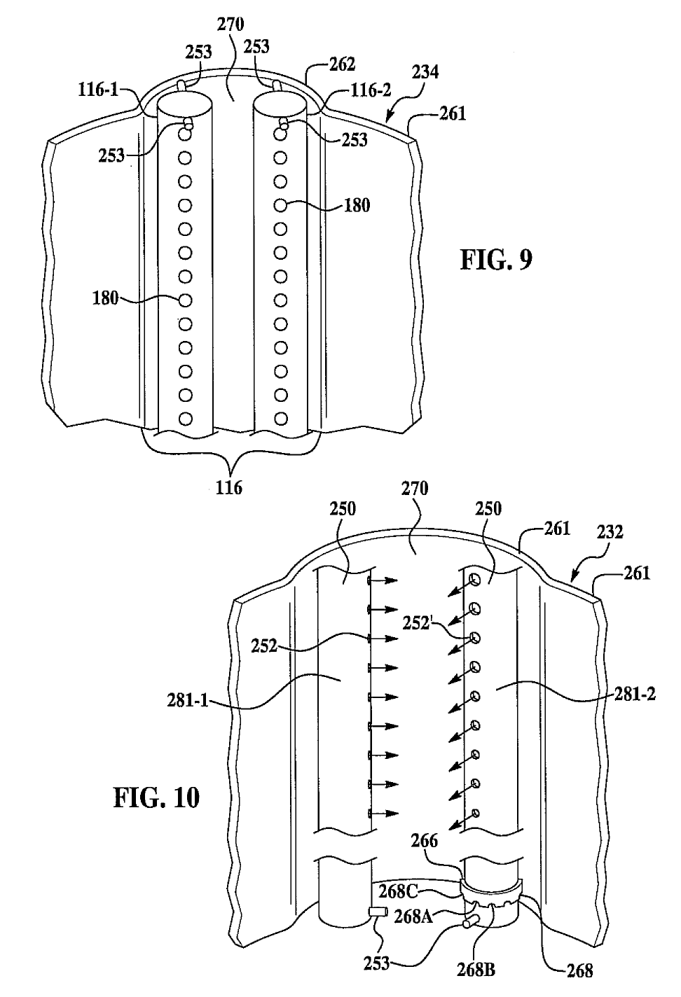

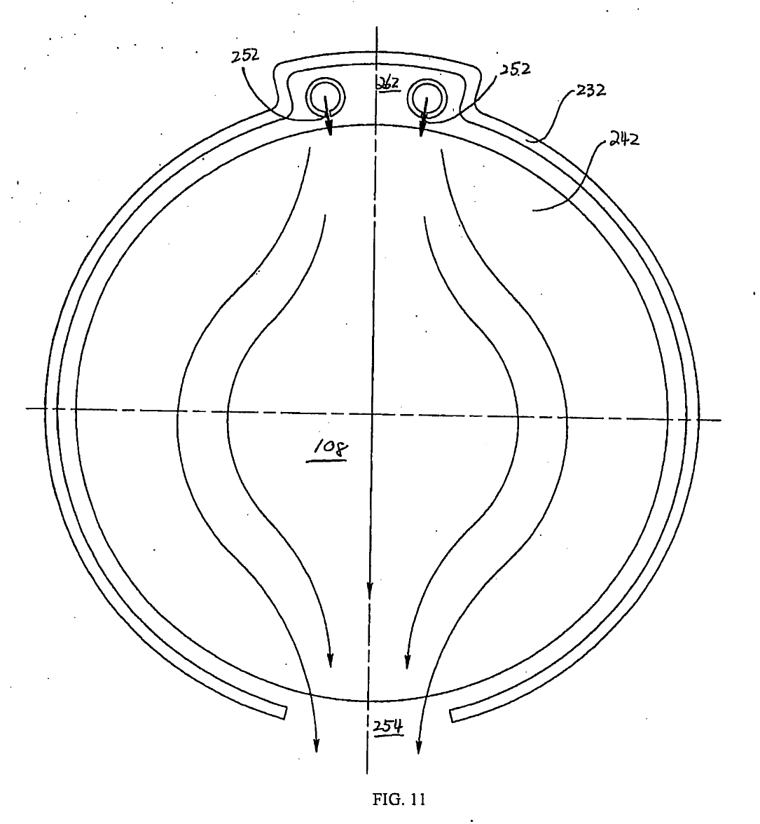

Referring to FIG. 9, the across-flow injection system 250 comprises one or more elongated tubes 251 rotatable about an axis perpendicular to the desired processing surfaces of the wafers 242. In the preferred embodiment, the elongated tubes 251 are provided with a plurality of injection ports or orifices 252 longitudinally distributed along the length of the tubes for directing reactant and other gases across the surface of each substrate. The injection port orifices 180 have the same area or in the alternative, the injection port orifices 252 can vary in area along the length of the injector tube 251, as depicted in FIG. 10. In addition, the inner diameter of two or more elongated tube injectors 116-1 and 116-2 are equal (FIG. 9), or in the alternative the inner diameter of two or more tube injectors 251 -1 and 251-2 can be different (FIG. 10). The injection orifices 180 or 252 are preferably equally spaced along the length of the injection tube 116 or 251, and in registry with slots 182 or 254 and wafer substrate surfaces 108 held in the boat 106.

In one embodiment, the elongated tubes 116 or 251 include an index pin 253 for locking the elongated tube in one of the notches 268 in the openings 266, and the injection ports or orifices 252 are formed in line with the index pin. Therefore, when the elongated tube is installed, the index pin 253 can be locked in one of the notches 268 and the injection orifices 180 or 252 are oriented in a direction as indicated by the appropriate notch 268. An indicator (not shown) located on the opposite end of tubes 251 further allows a user to adjust the location of the injection ports 252. This adjustment is performed before, during and after a thermal processing run without removal of the across-flow liner 232 from the vessel 234.

Of advantage, the bulging section 262 of the across-flow liner 232 accommodates the across-flow injection system 116 or 250 therein and the liner 232 is made conformal to the contour of the wafer carrier 106. This confirming of the liner 232 to the wafer carrier 106 reduces the gap between the liner and the wafer carrier, thereby reducing the vortices and stagnation in the gap regions between the liner inner wall and the wafer carrier 106, improving gas flow uniformity and the quality, uniformity, and repeatability of the deposited film.

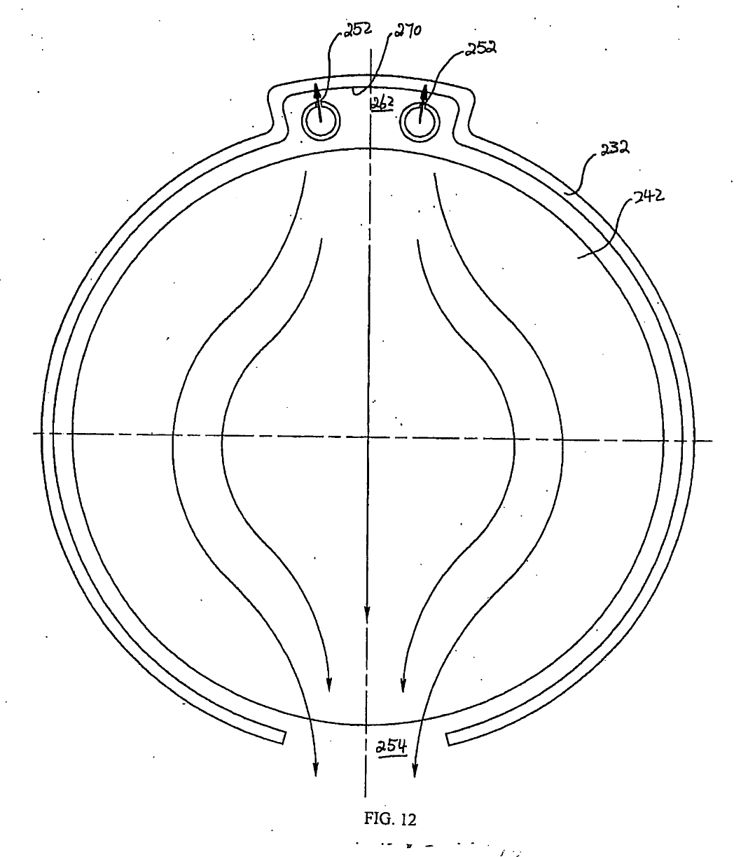

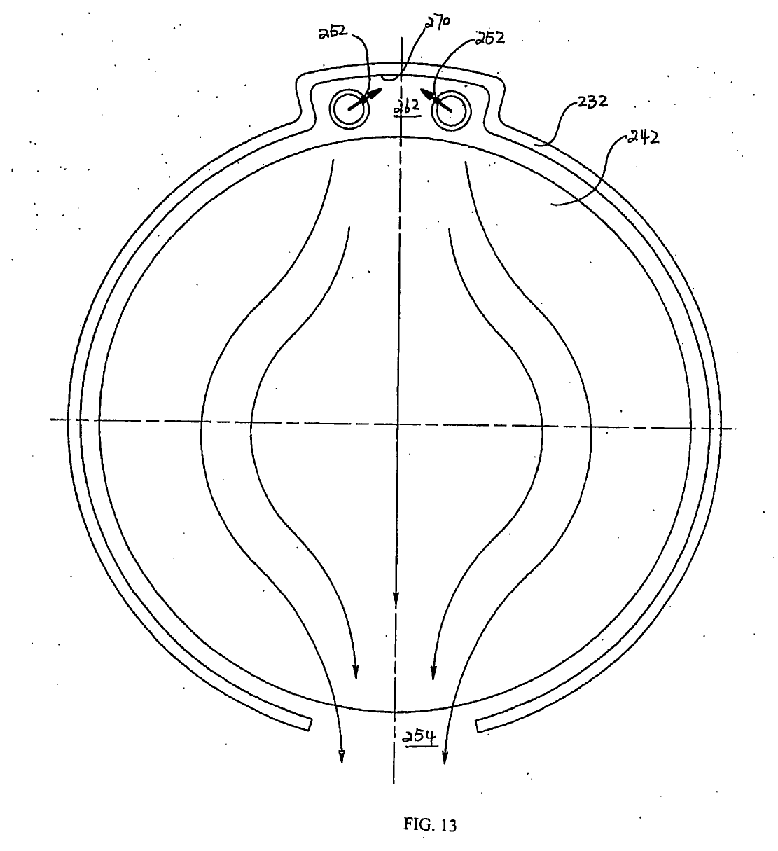

The base plate 124 has an opening 266 to receive the tube injectors. Notches 268 are formed in the base plate 124 to orient the injection ports 116-1, 116-2, 251-2 or 252-2 to a specific direction. Any number of notches 268 can be formed so that the elongated injection tubes can be adjusted 360 degrees relative to a fixed position and the injection ports 252 can be oriented in any direction as desired. For example, the index pin 253 the elongated tube injector 251-2 can be received in notch 268A so that the injection ports 252′ are oriented to face wafer substrates and the exit slots. As indicated in FIG. 11, gases exiting the injection ports 180 or 252 or 252′ impinge a liner wall 270 of the bulging section 262 prior to flowing across the surface of each substrate 108 to the exit slot 244. Alternatively, the index pins 253 in the elongated tube injectors 116-1/116-2 or 252-1/252-2 are received in notches so that the injection orifices 180 or 252 in each tube injector are oriented to face one another. As indicated in FIGS. 12-13, gases exiting the injection orifices 180 or 252 are directed to rotation to seat an index pin to a notch to a degree of rotation relative to a wafer 108.

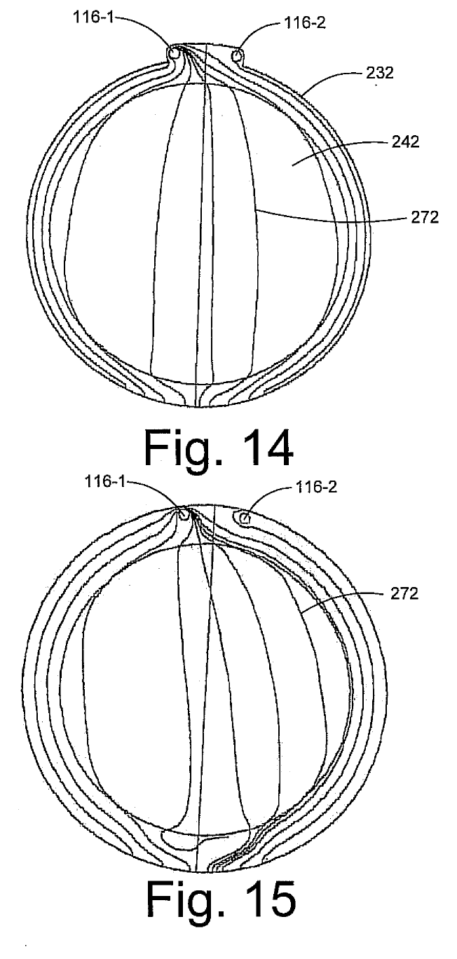

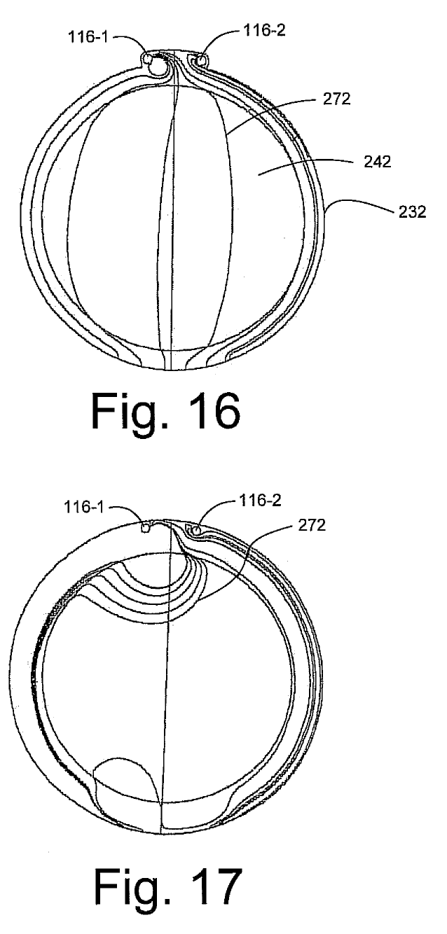

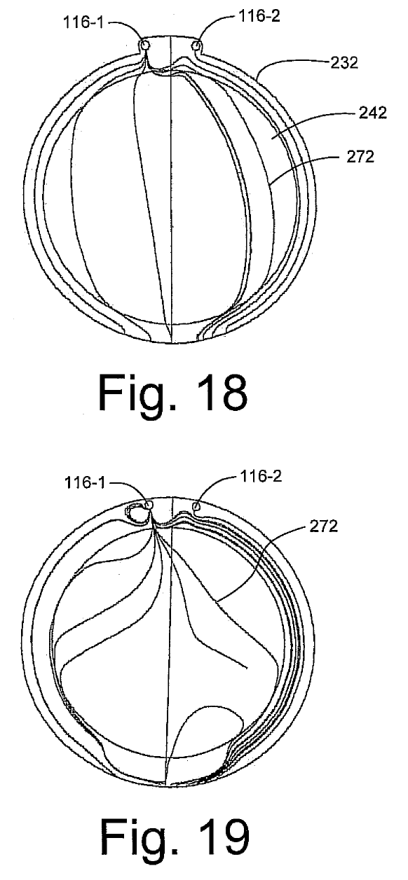

FIGS. 14-19 are “particle trace” graphics representing gas flow lines across the surface of a substrate inside a chamber. The graphics show particle traces 272 from injector orifices to an exhaust slot under various flow conditions. The flow momentum out of the first (leftmost) injector orifice is ten times greater than the second (rightmost) injector port. The across-flow liner of FIGS. 14, 16 and 18 and the rotation of injectors both provide advantages in providing uniform gas flows across the surface of a substrate as compared to existing gas delivery systems. The bulging section 262 in the across-flow liner 234 provides a mixing chamber for the gases exiting the injection ports prior to flowing across the surface of a substrate and thus facilitate momentum transfer of “ballistic mixing” of gases. In contrast, in the chamber with or without a bulging section, the gas flow across the surface of a substrate is less regular, as shown in FIGS. 15, 17 and 19 for a given rotational orientation of injectors.

In operation, a vacuum system produces a vacuum pressure in the reaction chamber 102. The vacuum pressure acts in the vertical direction of the vessel 101. The across-flow liner 232 is operative in response to the vacuum pressure to create a second vacuum inside the across-flow liner 232. The second vacuum pressure acts in a horizontal direction and across the surface of each substrate 108. Two gases, for example a first gas and a second gas, are introduced into the two elongated tubes 251 of the injection system 116 or 250 from two different gas sources. The gases exit the injection ports 252 on one side of the wafer 108 and pass as laminar flow across the wafer 242 to the slots 254 and between two adjacent wafers 108. Excessive gases or reaction byproducts are exhausted through the latitudinal slots 254 in the liner wall 232 cooperative with the injection orifices 180 or 252 in the elongated tube injectors.

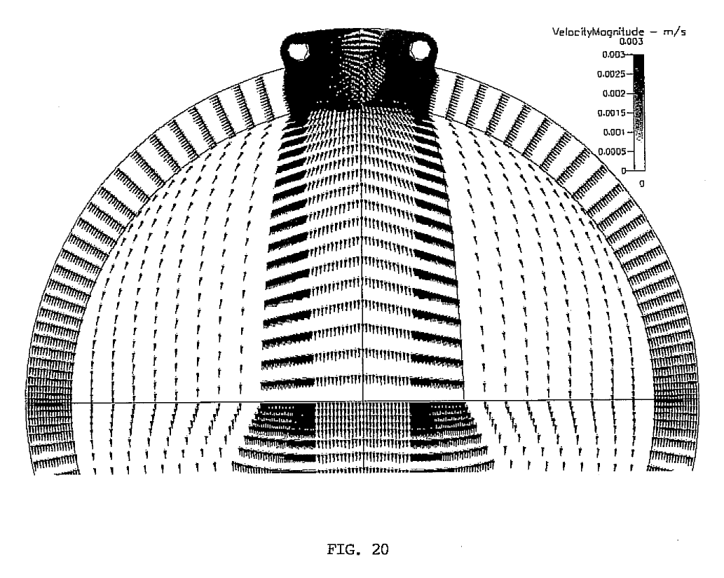

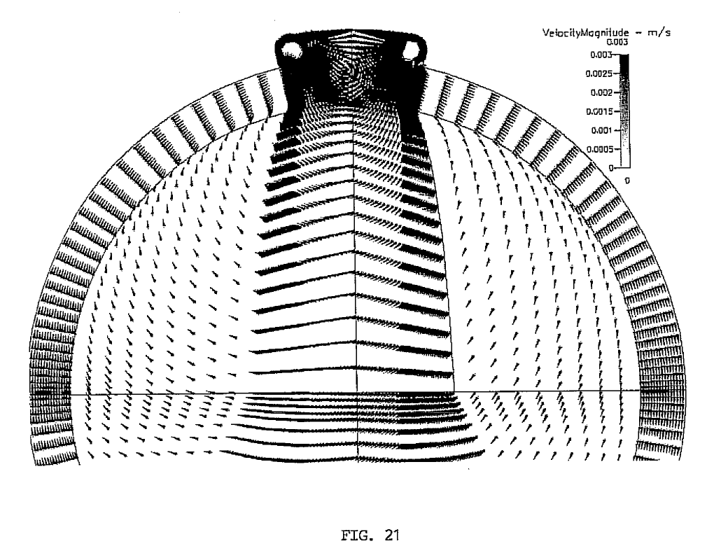

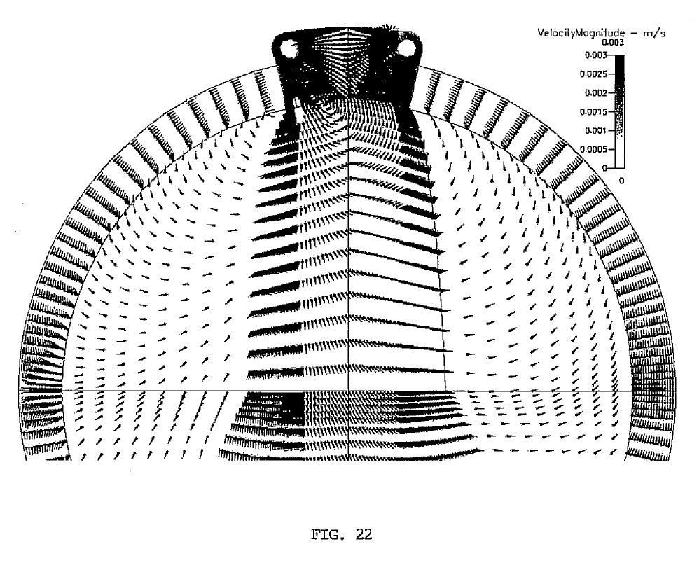

FIGS. 20-22 are Computational Fluid Dynamics (CFD) demonstrations for a thermal processing apparatus including an across-flow liner according to one embodiment of the present invention. The across-flow liner has a reduced diameter and is conformal to the wafer carrier. An across-flow injection system is accommodated in a bulging section of the liner. The injection system includes two elongated injection tubes each having a plurality of injection orifices to introduce reactant or other gases across the surface of each substrate. The injection orifices are oriented to face the liner inner surface (FIG. 20) such that the gases exiting the injection ports impinge the liner wall and mix in the bulging section prior to flowing across the surface of each substrate; the wafer center (FIG. 21); and face each other so that the gases exiting the injection ports impinge each other and mix prior to flowing across the surface of each substrate (FIG. 22). The gases introduced into the two tube injectors are trisilylamine and NH₃ respectively at 75 sccm.

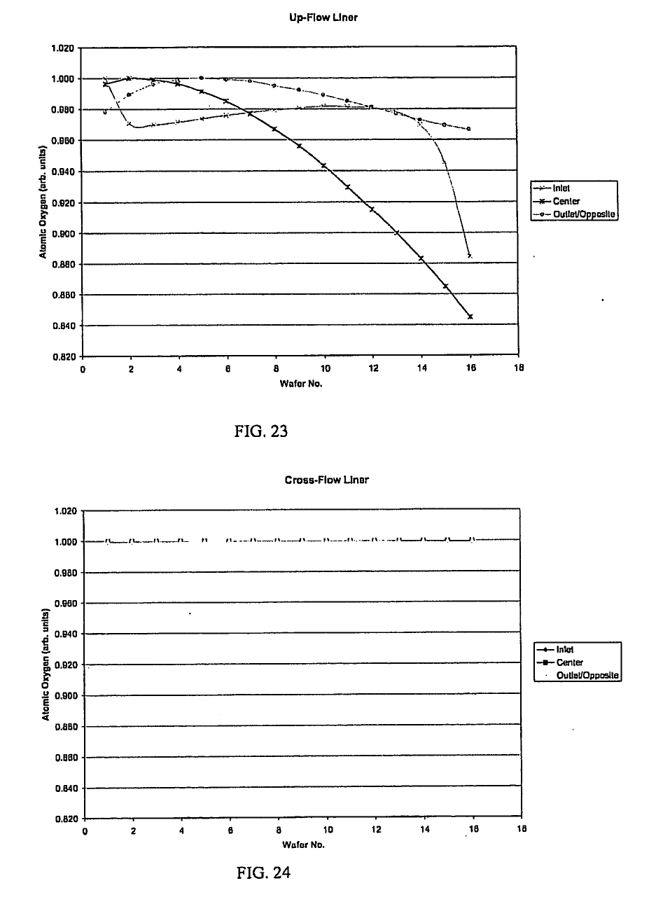

FIG. 23 is CFD demonstration for the concentration of atomic oxygen radicals as a result of introducing ozone into the injectors of a conventional up-flow furnace configuration lacking the injector and liner of the reactor depicted in FIG. 1. Wafer number 1 is at the bottom of the stack and the flow of the oxygen radicals is from the bottom to the top. The demonstration shows poor atomic oxygen concentration uniformity across the wafers and across the stack of wafers, resulting in poor uniformity of the desired film formation.

FIG. 24 is CFD demonstration for the concentration of atomic oxygen radicals as a result of introducing ozone into the injectors of an across-flow furnace configuration of FIG. 1. Wafer number 1 is at the bottom of the stack and the flow of the oxygen radicals is across flow. The demonstration shows very good atomic oxygen concentration uniformity WIN and WTW resulting in the desired film formation.

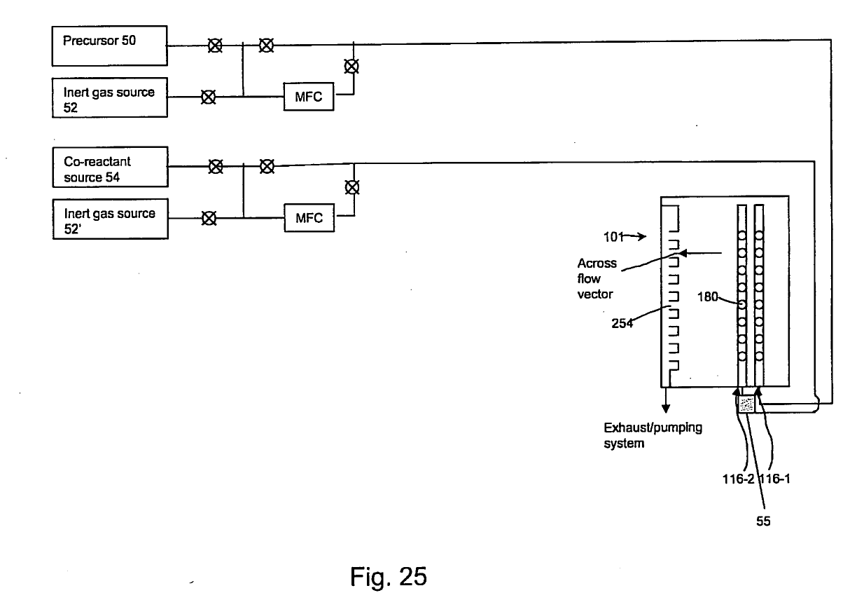

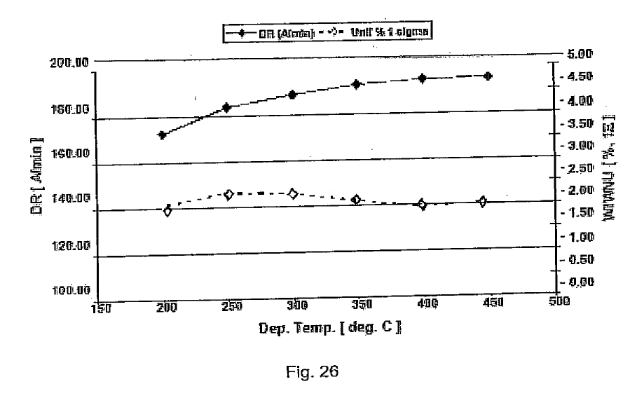

An exemplary gas flow schematic for a two injector reactor is depicted in FIG. 25. A precursor 50 is provided in fluid communication with injector 116-1 within vessel 101 with reference to FIG. 1. An inert gas source 52 is optionally interconnected to injector 116-1. With the use of conventional valves a mass flow controller (MFC) both source 50 and 52, or either source alone are selectively fed to the vessel 101 by injector 116-1. With registry of a wafer surface 104 and an exhaust slot 254 an across flow of reactants with a high degree of uniformity on a given wafer surface and vertically displaced wafers is achieved. In a similar manner, a co-reactant source 54 alone, an inert gas source 52′, or a combination thereof are selectively metered to injector 116-2. The co-reactant is optionally exposed to the discharge of a plasma generator 55 prior to contacting a wafer substrate. It is appreciated that with conventional gas connection schemes, inert gas sources 52′ is supplied by inert gas source 52. It is further appreciated that flowing inert gas through an injector when a reactant is not being provided through that injector tends to inhibit backflow into the unused injector.

### EXAMPLES

The ability to deposit a layer of material on a wafer substrate batch with uniformity WIW and WTW of the batch is provided in additional detail in the following working examples. These exemplary, nonlimiting examples are intended to illustrate the conditions under which inventive deposition might occur.

### Example 1

A batch of 20 wafers was dispersed along a 120 wafer carrier with substrate blanks filling the unused 100 positions. After stabilizing a wafer substrate temperature and an inert dinitrogen atmosphere, trisilylamine and ammonia gas are introduced into the reactor at flow rates of 15 and 225 sccm while the reactor total pressure is maintained at 3 Torr with a controlled flow of argon gas. The deposition is allowed to proceed for 30 minutes at a reaction temperature of 515° C. A deposition rate of 1.8 Angstroms per minute is noted. WIW uniformity for the resultant silicon nitride film is 2.3 thickness percent (three sigma) while WTW thickness variation is 2.6 percent. Auger spectroscopy indicated the resultant deposited layer of material to be devoid of carbon and chlorine and having less than 8 atomic percent substitution hydrogen for the silicon counterions.

### Examples 2-6

The process of Example 1 is repeated with a change in wafer substrate temperature. Comparable uniformity to that of Example 1 is noted while variations in deposition rate as a function of temperature are provided in Table 2 along with the comparative temperature and deposition rates for prior art precursors. Auger spectroscopy indicated the resultant deposited layer of material to be devoid of carbon and chlorine and having less than 10 atomic percent substitution hydrogen for the silicon counterions.

TABLE 2
Batch SiN Layer Deposition as a Function of Temperature

| | | Substrate Temp. | Deposition Rate |
|---|---|---|---|
| Example | Precursor | (° C.) | (Å/mm) |
| 1 | trisilylamine/NH₃ | 515 | 1.8 |
| 2 | trisilylamine/NH₃ | 525 | 4.0 |
| 3 | trisilylamine/NH₃ | 540 | 9.3 |
| 4 | trisilylamine/NH₃ | 550 | 10.3 |
| 5 | trisilylamine/NH₃ | 575 | 13 |
| 6 | trisilylamine/NH₃ | 600 | 18 |
| Comp. A | dichlorosilane/NH₃ | 750 | 17.3 |
| Comp. B | bis t-butylamino | 570 | 10.0 |
| | silane/NH₃ | | |

### Example 7

A low temperature oxide material layer is deposited with the reactor according to FIG. 1 with the reactor maintained at a total pressure of 7 Torr with dinitrogen as an inert gas, trisilylamine and oxygen being metered into the reactor at rates of 11 and 200 sccm, respectively. The nitrogen flow rate is approximately 500 sccm. The deposition rate and WIW nonuniformity (one sigma) as a function of deposition temperature between 200°0 and 450° C. is provided in FIG. 6. WTW variation is less than 3%. Auger spectroscopy indicated the resultant deposited layer of material to be devoid of carbon and chlorine and having less than 10 atomic percent substitution hydrogen for the silicon counterions.

### Example 8

A silicon oxynitride deposition layer is applied to a batch of wafer substrates with a total pressure of 2 Torr using dinitrogen as an inert gas, trisilylamine and N₂O flowing at rates of 15 and 300 sccm, respectively. With the simultaneous flow of trisilylamine and N₂O for a period of 30 minutes at a wafer substrate temperature of 525° C., silicon oxynitride deposition is noted to have occurred at a deposition rate of greater than 100 Angstroms per minute in a composition SiOₘNₙ where m is reproducibly 0.77 and n is 0.33. WIW variation is less than 3% three sigma and WTW thickness variation is less than 2.8%. Auger spectroscopy indicated the resultant deposited layer of material to be devoid of carbon and chlorine and having less than 10 atomic percent substitution hydrogen for the silicon counterions. The resultant deposited layer of material is observed to have an index of refraction of between 1.7 and 1.9 for various batches.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A batch of wafer substrates, each wafer substrate of the batch of wafer substrates having a surface, said batch of wafer substrates comprising:
a layer of material applied simultaneously onto the surface of each of the batch of wafer substrates to a thickness that varies less than four thickness percent three sigma within each wafer substrate exclusive of an edge boundary and having a wafer-to-wafer thickness variation of less than three percent, said material selected from the group consisting of SiOₓ where x is between 1.9 and 2.0 inclusive, Si_{y}N where y is between 0.75 and 1 inclusive, and SiOₘNₙ where n/(n+m) is between 0.2 and 0.4 inclusive; said layer of material substantially devoid of carbon and chlorine.

2. The batch of wafer substrates of claim 1 wherein each wafer substrate has a diameter of 300 millimeters.

3. The batch of wafer substrates of claim 1 wherein said material is Si_{y}N and hydrogen is present in an amount of equal to or less than 1-y when y is less than 1 and greater than 0.75.

4. The batch of wafers of claim 3 wherein the thickness varies less than three thickness percent within each wafer substrate.

5. The batch of wafers of claim 1 wherein said batch has from 2 to 200 substrates.

6. The batch of wafers of claim 1 wherein said material is SiOₘNₙ and m is between 0.6 and 0.8 and n is between 0.2 and 0.4 inclusive.

7. A process of simultaneously depositing a layer of material onto a batch of wafer substrates comprising:
feeding a Si—N—Si structure containing precursor into a reactor containing said batch of wafer substrates; and
reacting said Si—N—Si structure containing precursor at a wafer substrate temperature, total pressure, and precursor flow rate to form a layer of material onto a surface of each said batch of wafer substrates to a thickness that varies less than four thickness percent three sigma within each wafer across the surface exclusive of an edge boundary and having a wafer-to-wafer thickness variation of less than three percent, said layer substantially devoid of carbon and chlorine.

8. The process of claim 7 wherein said Si—N—Si structure containing precursor is trisilylamine.

9. The process of claim 7 further comprising introducing a coreactant into said reactor, said coreactant modifying a material layer deposition factor selected from the group consisting of: deposition mechanism and material layer composition.

10. The process of claim 9 wherein said coreactant is a nitrification reactant.

11. The process of claim 10 wherein said nitrification reactant is selected from the group consisting of: NH₃, HN₃, H₂N₂, secondary amines, tertiary amines, NH* and NH₂*; and said layer of material has the formula Si_{y}N where y is between 0.75 and 1 inclusive.

12. The process of claim 9 wherein said co-reactant is an oxidation reactant.

13. The process of claim 12 wherein said oxidation reactant is selected from the group consisting of: O₂, O₃, O*, OH*, H₂O, H₂O₂, NO, N₂O, NO₂, and combinations thereof.

14. The process of claim 12 wherein said layer of material is SiOₓ where x is between 1.9 and 2.0 inclusive.

15. The process of claim 8 wherein said wafer substrate temperature is less than 600° Celsius and said total pressure is less than 30 Torr.

16. The process of claim 9 wherein said wafer substrate temperature is less than 550° Celsius and said pressure is less than 10 Torr and said precursor and said coreactant are metered simultaneously into said reactor.

17. The process of claim 7 wherein said Si—N—Si structure containing precursor is fed into said reactor through a vertical tube injector having a plurality of orifices, at least one of said plurality of orifices in registry with each of said batch of wafer substrates and exit slits to create a flow across the surface of each of said batch of wafer substrates.

18. The process of claim 17 further comprising delivering a coreactant to said reactor through a second vertical tube injector having a second plurality of orifices, at least one of said secondary plurality of orifices in registry with each of said batch of wafer substrates and said exit slits.

19. The process of claim 18 wherein said precursor and said coreactant are simultaneously fed into said reactor.

20. The process of claim 18 wherein said coreactant includes oxygen atoms and nitrogen atoms to yield said layer of material having a composition SiOₘNₙ where m is between 0.6 and 0.8 inclusive and n is between 0.2 and 0.4 inclusive.

21. The process of claim 18 wherein said coreactant is an oxidation reactant and said layer of material has a composition SiOₓ where x is between 1.9 and 2.0 inclusive.

22. The process of claim 18 wherein said coreactant is a nitrification reactant and said layer of material has a composition Si_{y}N where y is between 0.75 and 1 inclusive.

23. The process of claim 18 wherein said coreactant is fed to said reactor at a rate of more than three times that of said precursor.

24. The process of claim 7 wherein said precursor has the formula: 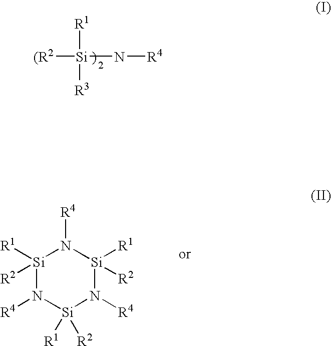
where R¹, R² and R³ are each independently hydrogen or C₁₋₈ alkyl, R¹ is SiH₃ when R₂ and R₃ are both hydrogen, and R⁴ is hydrogen, C₁₋₈ alkyl, or Si bonded to R¹, R² and R³.

25. The process of claim 9 further comprising exposing said coreactant to a plasma generator discharge.
